(19) United States
(12) Patent Application Publication
(10) Pub. No.: US 2024/0006254 A1
(43) Pub. Date: Jan. 4, 2024

(54) VOLTAGE CONTRAST SCAN AREA ON A WAFER

(71) Applicant: Intel Corporation, Santa Clara, CA (US)

(72) Inventors: Xiao WEN, Beaverton, OR (US); Dipto THAKURTA, Portland, OR (US); Sairam SUBRAMANIAN, Portland, OR (US)

(21) Appl. No.: 17/855,636

(22) Filed: Jun. 30, 2022

(51) Int. Cl. H01L 21/66; H01L 23/528; H01L 21/768

(52) U.S. Cl. CPC H01L 22/34; H01L 23/528; H01L 21/768

(57) ABSTRACT

Embodiments described herein may be related to apparatuses, systems, processes, and/or techniques for identifying device defects on a wafer substrate using voltage contrast techniques and electronic beam scans by scanning an area on a portion of the wafer that includes ends of a plurality of traces that extend from the scan area respectively to blocks on the wafer that include devices to be tested. During the electronic beam scan, ends of the plurality of traces within the scan area that are coupled with devices that are electrically shorted will appear bright, and those that are electrically open will appear dark. Other embodiments may be described and/or claimed.

### FIELD

Embodiments of the present disclosure generally relate to the field of semiconductor manufacturing, and in particular to testing for defects on a wafer.

### BACKGROUND

Continued growth in virtual machines, cloud computing, and portable devices will continue to increase the demand for high density transistors within chips and packages. In addition, there will be an increased need for high quality components with an improved efficiency in identifying device defects on a substrate or on a wafer.

### BRIEF DESCRIPTION OF THE DRAWINGS

FIG. 1 illustrates an example of a wafer substrate that includes a plurality of devices each within a separate area on the wafer substrate, with a plurality of signal lines extending from each area to a voltage contrast scan area on the wafer substrate for testing defects in the devices, in accordance with various embodiments.

FIGS. 2A-2D illustrate examples of signal terminals and/or ground terminals for devices within an area on a wafer substrate, in accordance with various embodiments.

FIGS. 3A-3C illustrate examples of multiple devices within an area on the wafer substrate that may be electrically coupled in series or in parallel for testing defects in the multiple devices, in accordance with various embodiments.

FIG. 4 illustrates an example of a voltage contrast scan area during an electronic beam test, in accordance with various embodiments.

FIG. 5 illustrates an example of a wafer substrate that includes multiple voltage contrast scan areas on the wafer substrate for testing various groups of devices for defects, in accordance with various embodiments.

FIG. 6 illustrates an example process for creating a voltage contrast scan area on a wafer substrate, in accordance with various embodiments.

FIG. 7 illustrates a computing device in accordance with one implementation of the invention.

FIG. 8 illustrates an interposer that includes one or more embodiments of the invention.

### DETAILED DESCRIPTION

Embodiments described herein are related to apparatuses, systems, techniques, and/or processes for creating voltage contrast (VC) structures on a substrate, which may be a wafer, to measure and/or monitor defect densities of devices on the substrate. In embodiments, the VC structures may be referred to as in-line test structures. In embodiments, traces may extend from each of the plurality of devices to a scan area on the substrate or wafer. In embodiments, the scan area may be a centralized area on a location of the substrate.

In embodiments, when the devices on the substrate or wafer are tested for opens or shorts using an electron beam (e-beam) technique, only the scan area needs to be observed to identify defects in the devices on the substrate or wafer. Depending on whether the traces display as bright or dark determines which device is in an open or a short state.

In embodiments, the traces may extend from various areas throughout the substrate, where the areas may be referred to as blocks. Each of the blocks may contain multiple devices that may be connected either in series or in parallel with a trace to the block. In embodiments, using an e-beam scan of the centralized scan area may be sufficient to determine which devices on the substrate or wafer are defective. In other embodiments, the e-beam scan of the scan area may define additional areas on the substrate or wafer that should be further scanned to identify individual defects, for example open or shorts, within a subgroup of devices in one or more blocks.

In embodiments, the blocks on the substrate may include electrically conductive contact structures that are electrically coupled with each trace that extends to the centralized scan area. In embodiments, there may be additional electrically conductive contact structures that may be electrically coupled with a ground, for example a ground of the substrate or the wafer that may electrically couple to one or more devices.

In embodiments, a device within a block that is electrically coupled with a trace that extends to the centralized scan area may also be electrically coupled with a ground at another location of the device. In this way, when the e-beam tool is scanning the scan area, the traces that are coupled with the devices that have a short will show as bright in the centralized scan area, and those traces that are coupled with devices that have an open will show as dark in the centralized scan area. In embodiments, a level of electrical conductivity within the device may also be indicated by a level of brightness of the traces in the scan area.

VC inspection is a defect inspection technique based on scanning electron microscopy. As an e-beam scans on metal lines, it positively charges the metal. Any grounded metal lines, for example which electrically connect to the wafer substrate, emits more electrons and presents brighter pattern in e-beam scan images. Any metal lines which are not grounded and which may be isolated from the substrate, which may be referred to as floating metal lines, emit less electrons and look darker in e-beam scan images.

The brightness difference among metal lines due to voltage difference (grounded versus not grounded) is called voltage contrast. If the brightness pattern in a VC image deviates from design, it shows defects in the underlying structures. When a floating structure turns bright, it indicates a short defect that connects the structure to a ground. If a structure that is designed to be grounded turns dark, it indicates an open defect that is not connected to a ground.

A VC structure is normally designed to be vulnerable to a specific type of defect. Typically, each VC structure is custom-designed to target a specific type of defect. For example, a target structure to detect contact via opens may have only a large dense region of contact vias, in various configurations, that are connected to a ground. As a result, the structure will not be useful to detect other defect modes, for example vias on gate opens, or other opens or shorts.

In legacy implementations, different types of VC structures are spread over a wafer area, which affects the lowest defect density that can be detected for devices on the wafer. While a developing process matures, the defect density of devices on the wafer typically goes down, and as a result it requires a large area, usually several square millimeters, to identify a single defect. Since the VC tool takes time to scan wafers, the tool scanning time for a wafer becomes significant, and it slows down the pace of semiconductor process design and manufacturing.

In embodiments, the speed at which an e-beam scan of VC structures may be significantly increased by localizing a scan area on a wafer that is associated with a plurality of devices on the wafer. As a result, a VC structure grid on a wafer that includes multiple block regions that contain various test structures/devices may be more efficiently scanned by scanning just a portion of the wafer, a scan area, that includes traces to each of the blocks that include VC structures. In embodiments, each block includes a signal terminal that electrically couples with the devices and connect to signal lines that lead to the scan area.

In implementation, an e-beam scan of a legacy substrate may take hours to collect defect data. In embodiments described herein, there may be at least a 10 times faster data collection to determine defects and/or defect density on a substrate.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

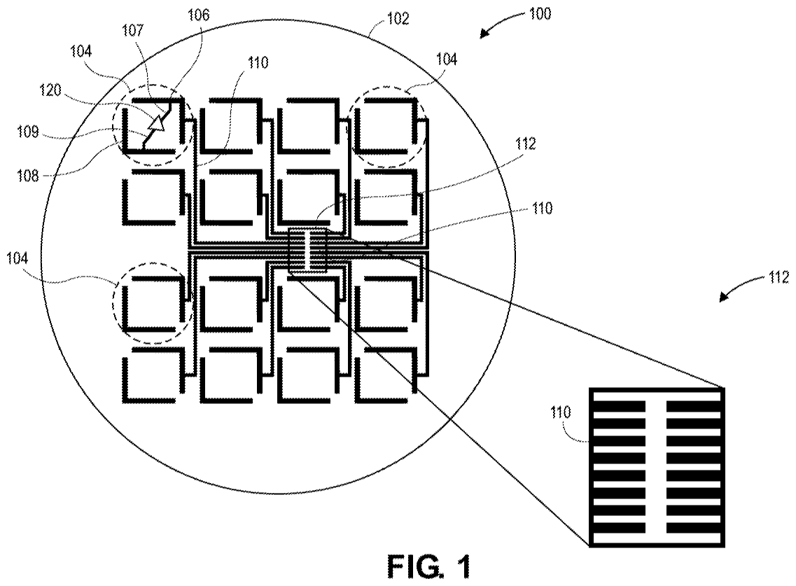

FIG. 1 illustrates an example of a wafer substrate that includes a plurality of devices each within a separate area on the wafer substrate, with a plurality of signal lines extending from each area to a voltage contrast scan area on the wafer substrate for testing defects in the devices, in accordance with various embodiments. Diagram 100 shows a top-down view of a substrate 102, which may also be referred to as a wafer substrate, which includes a plurality of blocks 104 on a surface of the substrate 102. In embodiments, the plurality blocks 104 represent different areas on the surface of the substrate 102.

In embodiments, each of the blocks 104 may include a signal terminal 106 that is electrically coupled with a trace 110. In embodiments, each trace 110 extends from each block 104 to a scan area 112 on the surface of the substrate 102. In embodiments, the trace 110 may be a metal trace on a surface of the substrate 102, where the metal may include copper, aluminum, cobalt, titanium, or some other electrically conductive metal or metal alloy that may be electrically isolated from the substrate 102. In embodiments, each of the traces 110 may be electrically isolated from each other. In embodiments, each of the traces 110 may be electrically isolated from a ground of the substrate 102.

In embodiments, each block 104 may also include a ground terminal 108. In embodiments, each block 104 may contain a device 120 (represented by a triangle) where a first portion of the device 120 may be electrically coupled with the signal terminal 106 using a signal connection 107. A second portion of the device 120 may be electrically coupled with the ground terminal 108 using a ground connection 109.

In embodiments, the device 120 may be any device that may be placed on the substrate 102 to be tested whether the device is in an open state or a short state. In embodiments, the device 120 may include but is not limited to VC structures to detect gate end-to-end shorts, contact end-to-end shorts, via opens, via to gate and via to contact shorts, metal to via opens, metal end-to-end shorts, metal side-to-side shorts, and the like.

One example of a device 120 may be a poly to poly device where n to n shorts are to be identified. In this example, the device 120 may appear to be two cones opposing each other, or one side of a cone is connected to the ground terminal 108 and a side of the other cone is connected to the signal terminal 106. If the poly end to end is correctly patterned as an open structure, then the signal terminal 106 will be electrically isolated from the ground terminal 108, and the trace 110 within the scan area 112 will appear dark under an e-beam scan. Otherwise, if there is a short in the poly to poly device, then the trace 110 within the scan area 112 will appear bright.

Substrate 102 includes 16 blocks 104 that are arranged in a 4×4 grid pattern, with each respective trace 110 for each block 104 ending within the scan area 112. During a VC test, the scan tool needs to only look at scan area 112 to determine the open or short status of each of the devices 120 within each of the blocks 104 on the substrate 102. In embodiments, a VC scanning electron microscopy (SEM) image may be used to capture whether the traces 110 are bright or dark. This may determine the conductivity information of each of the blocks 104, and may also indicate defect information for the devices 120. Note that scan area 112 is shown in a center region of the substrate 102. However, in other embodiments, the scan area 112 may be in any location on the substrate 102.

In embodiments as shown, a dimension of the scan area 112 may be 1000 μm² or less, and may have a dimension of 100 μm or less on each side. In embodiments, the blocks 104 are shown as rectangular; however, the blocks 104 in other implementations may be any shape. In embodiments, a distance of the traces 110 from a block 104 to the scan area 112 may be chosen based upon resistance value of the traces, a desired contrast of the traces 110 within the scan area 112, and a resolution capability of the e-beam tools used for inspection.

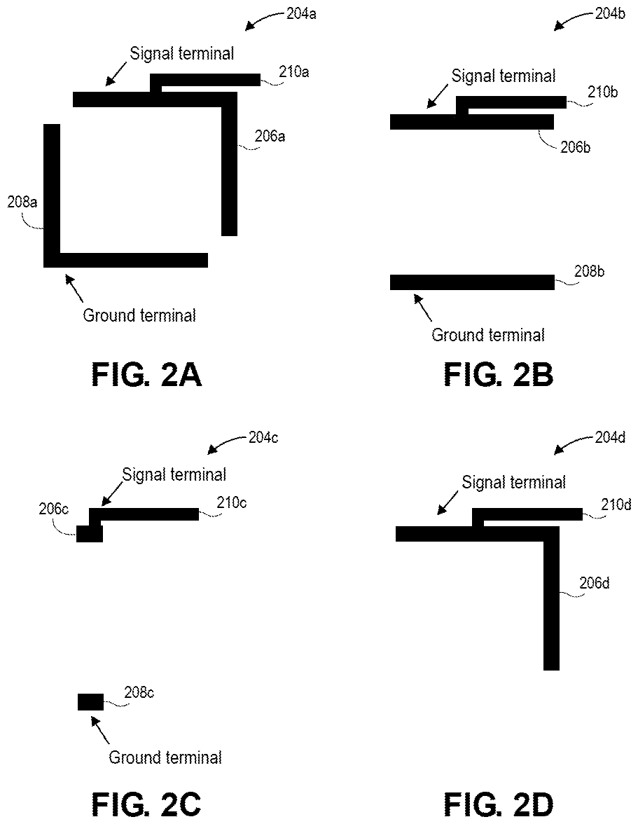

FIGS. 2A-2D illustrate examples of signal terminals and/or ground terminals for devices within an area on a wafer, in accordance with various embodiments. FIG. 2A shows block 204a that includes a signal terminal 206a that is connected with a trace 210a, and a ground terminal 208a. Block 204a, signal terminal 206a, trace 210a and ground terminal 208a may be similar to block 104, signal terminal 106, trace 110, and ground terminal 108 of FIG. 1.

As shown, the signal terminal 206a and the ground terminal 208a may be L-shaped, to allow a greater flexibility for connecting a device, such as device 120 of FIG. 1, to either the signal terminal 206a or the ground terminal 208a.

FIG. 2B shows block 204b, which may be similar to block 204a, where a signal terminal 206b is a straight bar, and is electrically coupled with the trace 210b. The ground terminal 208b may also be a straight bar. FIG. 2C shows block 204c, which may be similar to block 204a, where signal terminal 206c is at a single point that is coupled with trace 210c. In embodiments, the ground terminal 208c may be at a single point, and coupled with a ground.

FIG. 2D shows block 204d, which may be similar block 204a, where signal terminal 206d is an L-shaped that is coupled with a trace 210d. In this embodiment, the substrate (not shown), which may be similar to substrate 102 of FIG. 1, is grounded. Thus the device, such as device 120, may have one of its ports directly coupled with the grounded substrate. In other embodiments, the device, such as device 120, may have its own ground, and may only require coupling with the signal terminal 206d.

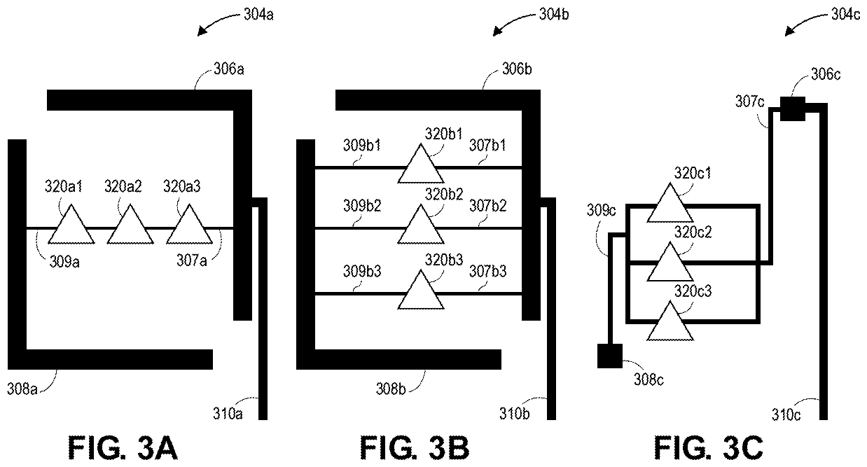

FIGS. 3A-3C illustrate examples of multiple devices within an area on the wafer that may be electrically coupled in series or in parallel for testing defects in the multiple devices, in accordance with various embodiments. In these embodiments, multiple devices, or multiple VC structures, may appear in a block.

FIG. 3A shows block 304a, which may be similar to block 104 of FIG. 1, which includes a signal terminal 306a that is coupled with a trace 310a. Three devices 320a1, 320a2, 320a3 are connected in series. The first device 320a1 may be coupled with a ground terminal 308a using ground connection 309a, and the third device 320a3 may be coupled with the signal terminal 306a using signal connection 307a. Thus, the combination of the three devices 320a1, 320a2, 320a3, may in effect form a larger test structure. In this configuration, each of the three devices 320a1, 320a2, 320a3 need to be short, for example not electrically open, in order for the trace 310a to appear bright within the scan area, which may be similar to scan area 112 of FIG. 1. In embodiments, if any one of the three devices 320a1, 320a2, 320a3 has an electrical open, the trace 310a would appear dark.

FIG. 3B shows block 304b, which may be similar to block 104 of FIG. 1, which includes a signal terminal 306b that is coupled with a trace 310b. Block 304b also includes a ground terminal 308b. Three devices 320b1, 320b2, 320b3 are connected in parallel. This configuration may be referred to as a comb structure. The first device 320b1 may be connected with the ground terminal 308b using ground connection 309b1 and connected with the signal terminal 306b using signal connection 307b1. The second device 320b2 may be connected with the ground terminal 308b using ground connection 309b2 and connected with the signal terminal 306b using signal connection 307b2. The third device 320b3 may be connected with the ground terminal 308b using ground connection 309b3 and connected with the signal terminal 306b using signal connection 307b3. In this configuration, if any of the three devices 320b1, 320b2, 320b3 has an electrical short, then the trace 310b would appear bright within the scan area (not shown, but may be similar to scan area 112 of FIG. 1). In embodiments, all of the three devices 320b1, 320b2, 320b3 would need to have an open for the trace 310b to appear dark.

FIG. 3C shows block 304c, which may be similar to block 204c of FIG. 2C, which includes a signal terminal 306c that is a point, which is coupled with a trace 310c. Block 304c also includes a ground terminal 308c which is at a point. The three devices 320c1, 320c2, 320c3 are connected in parallel, similar to the three devices 320b1, 320b2, 320b3 of FIG. 3B, where the three devices 320c1, 320c2, 320c3 are coupled to the ground terminal 308c using ground connection 309c, and are coupled to the signal terminal 306c using signal connection 307c.

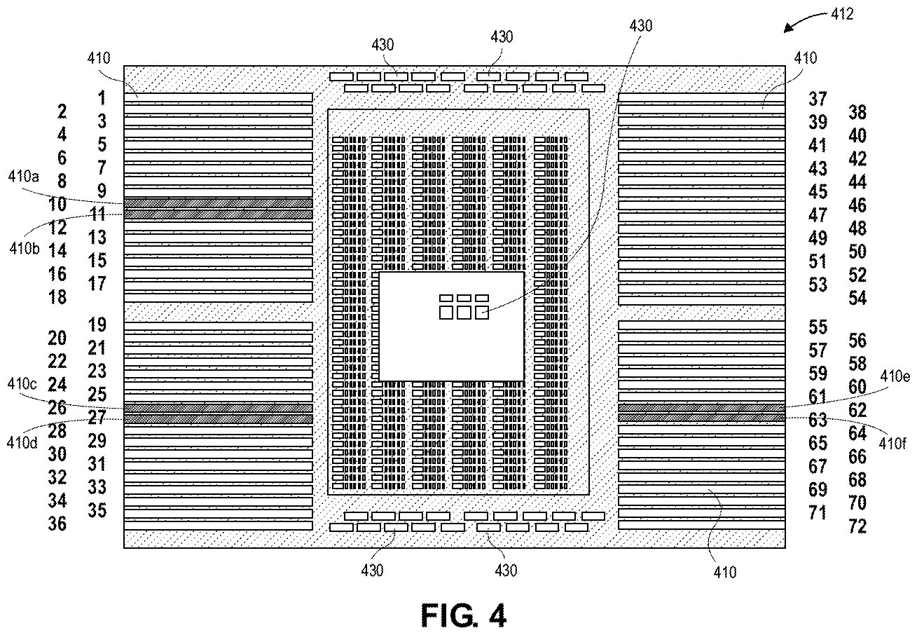

FIG. 4 illustrates an example of a voltage contrast scan area during an electronic beam test, in accordance with various embodiments. Scan area 412, which may be similar to scan area 112 of FIG. 1, shows a SEM image during an e-beam scan of a group of blocks, which may be similar to blocks 104 of FIG. 1.

Scan area 412 shows a total of 72 traces 410 which have various levels of brightness depending upon whether their respective blocks, such as block 104 of FIG. 1, includes devices such as device 120 that are either electrically open or electrically short. Traces 410 may be similar to traces 110 of FIG. 1. In this example, traces #10 410a, #11 410b, #26 410c, #27 410d, #62 410e, and #63 410f appear dark, indicating open defects in their respective blocks, such as blocks 104 of FIG. 1, on the substrate.

It should be noted that a block, such as block 104 of FIG. 1, that is associated with a trace 410 within scan area 412 indicates a defect, either by displaying bright or dark, and there are a plurality of devices within the block, the VC scanning tool may then move to that associated block for a more detailed scan to determine which of the specific devices may be operating correctly or may be defective. For example, with respect to FIG. 3A, the individual electrical connections between the devices 320a1, 320a2, 320a3 may be checked to determine which are bright (short) versus dark (open).

In addition, the scan area 412 may include reference areas 430 within the center portion of the scan area 412. In embodiments, the reference areas 430 may be either bright or dark, and may be used to evaluate the brightness or darkness of the traces 410. It should be noted that, depending upon the severity of the short in a device, such as a device 120 within block 104 of FIG. 1, the resistance value resulting from the severity of the short may cause a brightness of a trace 410 to be somewhat dimmed. In embodiments, the reference areas 430 may be used to evaluate the various levels of brightness to identify a characteristic of a short or an open in the device.

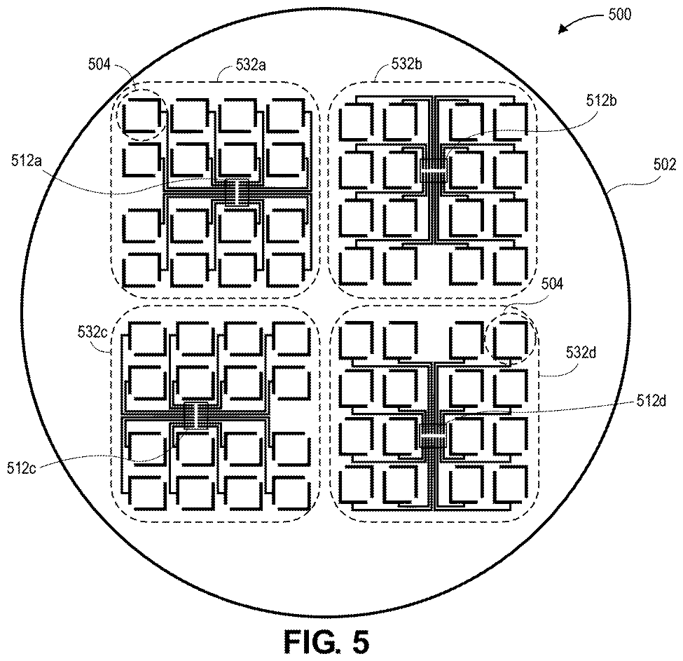

FIG. 5 illustrates an example of a wafer that includes multiple voltage contrast scan areas on the wafer for testing various groups of devices for defects diagram 500, in accordance with various embodiments. The substrate 502, which may be similar to substrate 102 of FIG. 1, includes a plurality of blocks 504, which may be similar to blocks 104 of FIG. 1. However, as is shown, the blocks 504 may be grouped into sections 532a, 532b, 532c, 532d, with each having its own scan area 512a, 512b, 512c, 512d, respectively. In embodiments, the plurality of blocks 504 may or may not be placed next to each other.

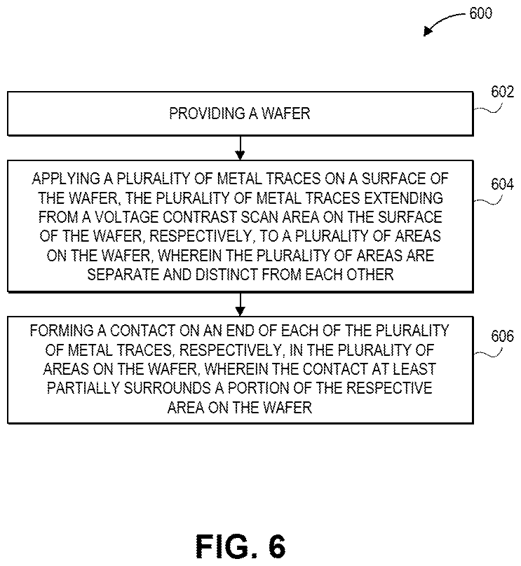

FIG. 6 illustrates an example process for creating a voltage contrast scan area on a wafer, in accordance with various embodiments. Process 600 may be performed using apparatus, systems, techniques, or processes described herein, in particular with respect to FIGS. 1-5.

At process block 602, the process may include providing a wafer. In embodiments, the wafer may be similar to substrate 102 of FIG. 1, or of substrate 502 of FIG. 5. In embodiments, the wafer may be a silicon wafer.

At process block 604, the process may further include applying a plurality of metal traces on a surface of the wafer, the plurality of metal traces extending from a voltage contrast scan area on the surface of the wafer, respectively, to a plurality of areas on the wafer, wherein the plurality of areas are separate and distinct from each other. In embodiments, the metal traces may be similar to traces 110 of FIG. 1, traces 210a, 210b, 210c, 210d of FIGS. 2A-2D, traces 310a, 310b, 310c of FIGS. 3A-3C, or traces 410 of FIG. 4. In embodiments, the voltage contrast scan area may be similar to scan area 112 of FIG. 1, scan area 412 of FIG. 4, or scan areas 512a, 512b, 512c, 512d of FIG. 5. In embodiments, the plurality of areas on the wafer may be similar to blocks 104 of FIG. 1, blocks 204a, 204b, 204c, 204d of FIGS. 2A-2D, blocks 304a, 304b, 304c of FIGS. 3A-3C, or blocks 504 of FIG. 5.

At process block 606, the process may further include forming a contact on an end of each of the plurality of metal traces, respectively, in the plurality of areas on the wafer, wherein the contact at least partially surrounds a portion of the respective area on the wafer. In embodiments, the contact may be similar to signal terminal 106 of FIG. 1, signal terminal 206a, 206b, 206c, 206d of FIGS. 2A-2D, or signal terminal 306a, 306b, 306c of FIGS. 3A-3C.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

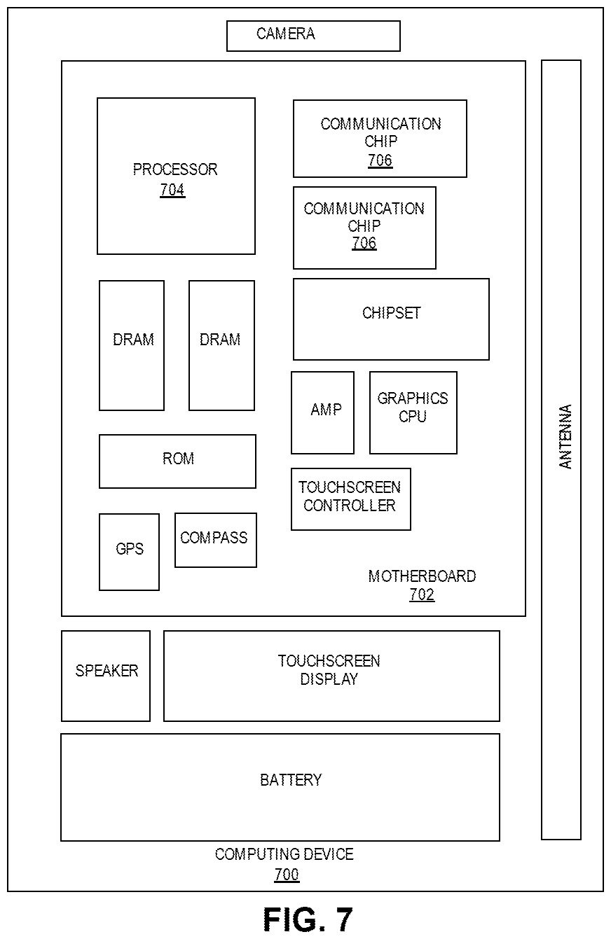

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices, such as MOS-FET transistors built in accordance with implementations of the invention.

In further implementations, another component housed within the computing device 700 may contain an integrated circuit die that includes one or more devices, such as MOS-FET transistors built in accordance with implementations of the invention.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

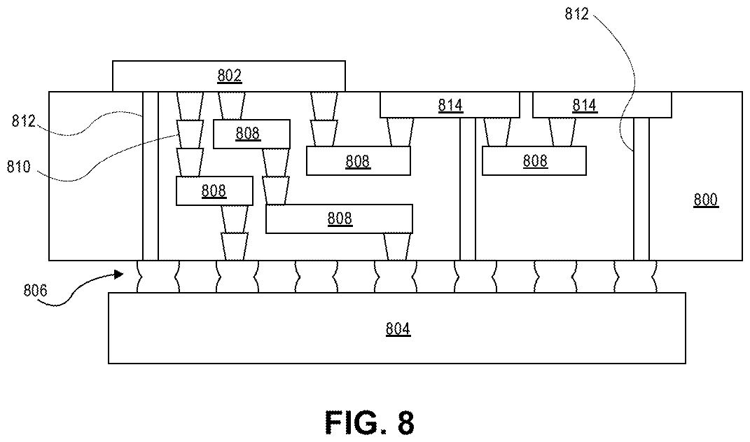

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

The following paragraphs describe examples of various embodiments.

### EXAMPLES

Example 1 is an apparatus comprising: a substrate; a plurality of devices on the substrate; a plurality of electrically conductive traces on the substrate, wherein each of the plurality of electrically conductive traces has a first end and a second end opposite the first end, and wherein each of the plurality of electrically conductive traces is electrically coupled at the first end, respectively, with each of the plurality of devices; wherein the second end of the each of the plurality of electrical traces is within a scan area on the substrate, and wherein the each of the plurality of electrically conductive traces are not directly electrically coupled with each other; and wherein the plurality of devices are electrically coupled with a ground.

Example 2 includes the apparatus of example 1, or of any other example or embodiment herein, wherein the plurality of electrically conductive traces is a first plurality of electrically conductive traces; and further comprising: a second plurality of electrically conductive traces on the substrate, wherein each of the second plurality of electrically conductive traces is electrically coupled, respectively, with each of the plurality of devices; and wherein each of the second plurality of electrically conductive traces is electrically coupled with the ground.

Example 3 includes the apparatus of example 1, or of any other example or embodiment herein, wherein the plurality of devices include components of a transistor structure.

Example 4 includes the apparatus of example 1, or of any other example or embodiment herein, wherein a first port of each of the plurality of devices is directly electrically coupled, respectively, with the first end of the each of the plurality of electrically conductive traces, and wherein a second port of each of the plurality devices is electrically coupled with the ground.

Example 5 includes the apparatus of example 1, or of any other example or embodiment herein, wherein the ground is a ground of the substrate.

Example 6 includes the apparatus of example 1, or of any other example or embodiment herein, wherein the plurality of devices, the plurality of electrically conductive traces, and the scan area are on a same side of the substrate.

Example 7 includes the apparatus of example 1, or of any other example or embodiment herein, wherein a dimension of the scan area is 1000 μm² or less.

Example 8 includes the apparatus for example 1, or of any other example or embodiment herein, wherein the first end of each of the plurality of electrically conductive traces includes a structure to facilitate electrical coupling with its respective device.

Example 9 includes the apparatus of example 1, or of any other example or embodiment herein, wherein the second end of the each of the plurality of electrically conductive traces are arranged in a grid pattern within the scan area.

Example 10 includes the apparatus of example 1, or of any other example or embodiment herein, wherein the plurality of devices are arranged on the substrate in a grid pattern.

Example 11 includes the apparatus of example 1, or of any other example or embodiment herein, wherein each of the plurality of devices further include a plurality of sub devices.

Example 12 includes the apparatus of example 11, or of any other example or embodiment herein, wherein a first of the each of the plurality of sub devices is electrically coupled with the ground, wherein a second of the each of the plurality of sub devices is electrically coupled with one of the plurality of electrically conductive traces, and wherein the plurality of sub devices are electrically coupled with each other in series.

Example 13 includes the apparatus of example 11, or of any other example or embodiment herein, wherein each of the plurality of sub devices is electrically coupled with the ground, and wherein each of the plurality of sub devices is electrically coupled with one of the plurality of electrically conductive traces.

Example 14 includes the apparatus of example 1, or of any other example or embodiment herein, wherein a brightness of a second end of one of the electrically conductive traces during an electronic beam scan identifies whether the device corresponding with the one of the plurality of electrically conductive traces has a short defect or an open defect.

Example 15 includes the apparatus of example 1, or of any other example or embodiment herein, wherein the plurality of electrically conductive traces include signal lines that include a metal.

Example 16 includes the apparatus of example 15, or of any other example or embodiment herein, wherein the metal includes copper.

Example 17 is a wafer comprising: a plurality of areas on a surface of the wafer; a scan area on the surface of the wafer; and a plurality of electrically conductive traces, each of the plurality of electrically conductive traces extending from the scan area, respectively, to an electrical contact in each of the plurality of areas, wherein the plurality of electrically conductive traces are not directly electrically coupled with each other.

Example 18 includes the wafer of example 17, or of any other example or embodiment herein, further comprising a plurality of devices, wherein one or more of the plurality of devices are located, respectively, in each of the plurality of areas on the surface of the wafer.

Example 19 includes the wafer of example 18, or of any other example or embodiment herein, wherein for each of the plurality of areas on the surface of the wafer, the one or more of the plurality of devices is electrically coupled with the electrical contact.

Example 20 includes the wafer of example 17, or of any other example or embodiment herein, wherein the plurality of areas are arranged in a grid pattern.

Example 21 includes the wafer of example 17, or of any other example or embodiment herein, wherein the scan area is separate and distinct from the plurality of areas, and wherein a dimension of the scan area has a length of 100 μm or less and a width of 100 μm or less.

Example 22 includes the wafer of example 17, or of any other example or embodiment herein, wherein the electrical contact in the each of the plurality of areas at least partially surrounds the each of the plurality of areas.

Example 23 is a method comprising: providing a wafer; applying a plurality of metal traces on a surface of the wafer, the plurality of metal traces extending from a voltage contrast scan area on the surface of the wafer, respectively, to a plurality of areas on the wafer, wherein the plurality of areas are separate and distinct from each other; and forming a contact on an end of each of the plurality of metal traces, respectively, in the plurality of areas on the wafer, wherein the contact at least partially surrounds a portion of the respective area on the wafer.

Example 24 includes the method of example 23, or of any other example or embodiment herein, further comprising: placing a plurality of devices, respectively, in the plurality of areas on the surface of the wafer; and electrically coupling each of the plurality of devices, respectively, to the contact the plurality of areas on the wafer.

Example 25 includes the method of example 23, or of any other example or embodiment herein, further comprising: electrically coupling each of the plurality of devices with a ground of the substrate.

1. An apparatus comprising:
a substrate;
a plurality of devices on the substrate;
a plurality of electrically conductive traces on the substrate, wherein each of the plurality of electrically conductive traces has a first end and a second end opposite the first end, and wherein each of the plurality of electrically conductive traces is electrically coupled at the first end, respectively, with each of the plurality of devices;
wherein the second end of the each of the plurality of electrical traces is within a scan area on the substrate, and wherein the each of the plurality of electrically conductive traces are not directly electrically coupled with each other; and
wherein the plurality of devices are electrically coupled with a ground.

2. The apparatus of claim 1, wherein the plurality of electrically conductive traces is a first plurality of electrically conductive traces; and further comprising:
a second plurality of electrically conductive traces on the substrate, wherein each of the second plurality of electrically conductive traces is electrically coupled, respectively, with each of the plurality of devices; and
wherein each of the second plurality of electrically conductive traces is electrically coupled with the ground.

3. The apparatus of claim 1, wherein the plurality of devices include components of a transistor structure.

4. The apparatus of claim 1, wherein a first port of each of the plurality of devices is directly electrically coupled, respectively, with the first end of the each of the plurality of electrically conductive traces, and wherein a second port of each of the plurality devices is electrically coupled with the ground.

5. The apparatus of claim 1, wherein the ground is a ground of the substrate.

6. The apparatus of claim 1, wherein the plurality of devices, the plurality of electrically conductive traces, and the scan area are on a same side of the substrate.

7. The apparatus of claim 1, wherein a dimension of the scan area is 1000 nm 2 or less.

8. The apparatus of claim 1, wherein the first end of each of the plurality of electrically conductive traces includes a structure to facilitate electrical coupling with its respective device.

9. The apparatus of claim 1, wherein the second end of the each of the plurality of electrically conductive traces are arranged in a grid pattern within the scan area.

10. The apparatus of claim 1, wherein the plurality of devices are arranged on the substrate in a grid pattern.

11. The apparatus of claim 1, wherein each of the plurality of devices further include a plurality of sub devices.

12. The apparatus of claim 11, wherein a first of the each of the plurality of sub devices is electrically coupled with the ground, wherein a second of the each of the plurality of sub devices is electrically coupled with one of the plurality of electrically conductive traces, and wherein the plurality of sub devices are electrically coupled with each other in series.

13. The apparatus of claim 11, wherein each of the plurality of sub devices is electrically coupled with the ground, and each of the plurality of sub devices is electrically coupled with one of the plurality of electrically conductive traces.

14. The apparatus of claim 1, wherein a brightness of a second end of one of the electrically conductive traces during an electronic beam scan identifies whether the device corresponding with the one of the plurality of electrically conductive traces has a short defect or an open defect.

15. The apparatus of claim 1, wherein the plurality of electrically conductive traces include signal lines that include a metal.

16. The apparatus of claim 15, wherein the metal includes copper.

17. A wafer comprising:
a plurality of areas on a surface of the wafer;
a scan area on the surface of the wafer; and
a plurality of electrically conductive traces, each of the plurality of electrically conductive traces extending from the scan area, respectively, to an electrical contact in each of the plurality of areas, wherein the plurality of electrically conductive traces are not directly electrically coupled with each other.

18. The wafer of claim 17, further comprising a plurality of devices, wherein one or more of the plurality of devices are located, respectively, in each of the plurality of areas on the surface of the wafer.

19. The wafer of claim 18, wherein for each of the plurality of areas on the surface of the wafer, the one or more of the plurality of devices is electrically coupled with the electrical contact.

20. The wafer of claim 17, wherein the plurality of areas are arranged in a grid pattern.

21. The wafer of claim 17, wherein the scan area is separate and distinct from the plurality of areas, and wherein a dimension of the scan area has a length of 100 μm or less and a width of 100 μm or less.

22. The wafer of claim 17, wherein the electrical contact in the each of the plurality of areas at least partially surrounds the each of the plurality of areas.

23. A method comprising:
providing a wafer;
applying a plurality of metal traces on a surface of the wafer, the plurality of metal traces extending from a voltage contrast scan area on the surface of the wafer, respectively, to a plurality of areas on the wafer, wherein the plurality of areas are separate and distinct from each other; and
forming a contact on an end of each of the plurality of metal traces, respectively, in the plurality of areas on the wafer, wherein the contact at least partially surrounds a portion of the respective area on the wafer.

24. The method of claim 23, further comprising:
placing a plurality of devices, respectively, in the plurality of areas on the surface of the wafer; and
electrically coupling each of the plurality of devices, respectively, to the contact the plurality of areas on the wafer.

25. The method of claim 23, further comprising: electrically coupling each of the plurality of devices with a ground of the substrate.
